(19) United States
(12) Patent Application Publication
(10) Pub. No.: US 2011/0317854 A1
(43) Pub. Date: Dec. 29, 2011

(54) Speaker voume control with inidividual input and output impedance converters

(76) Inventor: Jeffery Kunio Aragaki, Morgan Hill, CA (US)

(21) Appl. No.: 12/803,410

(22) Filed: Jun. 25, 2010

(51) Int. Cl. H03G 3/00

(52) U.S. Cl. 381/107

(57) ABSTRACT

A passive circuit that provides a variable means of controlling the audio speaker's volume level from a music instrument tube amplifier, without reducing the reactance of the audio speaker, allowing the audio speaker to reproduce sound in a natural way. The invention utilizes a multiple tapped input and a multiple tapped output transformers, along with a multiple tapped series resistive network, providing volume level control without reducing the audio speaker's reactance with a parallel resistive load. The input transformer with multiple taps, provides a variable means to impedance match the circuit to a plurality of impedance values available in common music instrument tube amplifiers. The separate output transformer with multiple taps, provides a variable means to impedance match the circuit to a plurality of impedance values available in common audio speakers. By utilizing the individual multiple tapped input and output transformers, the invention provides a means of converting the output impedance of the music instrument tube amplifier and separately converting an audio speaker with a dissimilar impedance value, to match the impedance requirements of the volume control circuit.

### CROSS-REFERENCE TO RELATED APPLICATIONS

This application claims the benefit of provisional patent application Ser. No. 60/269,581, filed on 2009 Jun. 27 by the present inventor.

### FEDERALLY SPONSORED RESEARCH

Not Applicable

### SEQUENCE LISTING OR PROGRAM

Not Applicable

### BACKGROUND

1. Field

This application relates to audio speaker volume control as used with music instrument tube amplifiers.

2. Background Art

This invention relates to controlling an audio speaker's volume level from a music instrument tube amplifier, in particular an electric guitar tube amplifier. Often guitarists prefer to increase the volume control of the tube amplifier until a distorted tone is heard. This distorted tone is often a desired sound and is partially achieved by overdriving the power tube section of the amplifier. However, the point where the power tubes are driven into producing a distorted tone, the sound pressure level from the audio speaker can be greater than desired.

In prior art, a passive device is added between the guitar tube amplifier and audio speaker that allows volume control of the audio speaker. Common circuitry includes an “L”, “Variable L” or “T” resistive load network. Scholz in U.S. Pat. No. 4,363,934 teaches a resistive ladder network in parallel with the audio speaker provides an adjustable volume control and as the volume is reduced, a lower value resistor is placed in parallel with the audio speaker.

An audio speaker is a reactive device whose impedance is frequency dependent. The impedance of a typical audio speaker will vary from its DC resistance value up to double the DC resistance value or greater. Placing a resistive load in parallel with the audio speaker reduces the audio speaker's reactance.

The prior art passive devices and inventions have a shortcoming in that they place a resistive load in parallel with the audio speaker, reducing the audio speaker's reactance, which limits the audio speaker's ability to reproduce a natural sound. In order for the prior art passive devices to provide a variable means of controlling the audio speaker's volume level, the prior art passive devices place resistive loads with decreasing resistance values in parallel with the audio speaker. Based on Ohm's law, as the parallel resistor's value is reduced, the combined impedance of the resistor and audio speaker in parallel is reduced. Therefore, the quality of sound is reduced due to the reduction of the audio speaker's overall reactance, which in turn, reduces the audio speaker's ability to reproduce a natural sound.

Manufacturers of guitar tube amplifiers typically recommend; for safe operation and maximum efficiency of their product, the output section of the amplifier be coupled to a speaker with an equivalent impedance rating.

The typical output impedance available in common guitar tube amplifiers are 2, 4, 8 or 16 ohm. The output impedance of the guitar tube amplifier can be either fixed at a single impedance value or be selectable. All audio speakers are rated with a single impedance value, most commonly 4, 8 or 16 ohm.

The prior art passive devices have another shortcoming in that they do not incorporate a separate variable circuit to match the output impedance of the guitar tube amplifier to their invention and a separate variable circuit to match the impedance of the audio speaker to their invention. Therefore, the prior art passive devices do not provide a means of converting and matching the impedances of a guitar tube amplifier and an audio speaker whose impedance are dissimilar.

### BACKGROUND OF THE INVENTION

One important object of the invention is to provide a variable volume control between the guitar tube amplifier and the audio speaker, with no reduction in the audio speaker's reactance, throughout the entire volume control range, allowing the audio speaker to react unimpeded and reproduce a natural sound.

Another object is to maintain constant load impedance to the output section of the guitar tube amplifier, throughout entire range of the audio speaker volume control.

Another object is to provide a means for guitar tube amplifiers and audio speakers with dissimilar impedances to be impedance matched, by utilizing separate input and output impedance converting circuits.

### SUMMARY OF THE INVENTION

To accomplish the objects of this invention, a circuit designed with a multiple tapped input transformer is utilized. The taps on the primary side of the input transformer are coupled to a multiple position rotary switch, providing a variable means of converting the circuit's input impedance. Guitar tube amplifiers are available with a plurality of output impedance values and the circuit's multi-position rotary switch provides a variable means of allowing the proper circuit impedance to be selected, matching the output impedance of the guitar tube amplifier.

The secondary side of the multiple tapped input transformer, couples to the input side of a dual pole, multiple position rotary switch. The output side of the dual pole, multiple position rotary switch couples to a multiple tapped, series resistive ladder network. The output side of the dual pole, multiple position rotary switch provides a means for one tap of the multiple tapped, series resistive ladder to be selected. The input side of the dual pole, multiple position rotary switch simultaneously couples to the appropriate tap on the secondary side of the multiple tapped input transformer. The dual pole, multiple position rotary switch provides a means of maintaining a proper load impedance towards the guitar tube amplifier, throughout the volume control range. The dual pole, multiple position rotary switch and the multiple taps of a series resistive ladder network provide a means of variably controlling the audio speaker's volume.

The output of the series resistive ladder network is coupled to the primary side of a multiple tapped output transformer. The circuit's resistive ladder network is coupled in a series only method with respect to the multiple tapped output transformer and audio speaker, intentionally avoiding the use of a parallel resistive load across the speaker, therefore, not affecting the reactance of the audio speaker.

The secondary side of the multiple tapped output transformer is coupled to a multiple position rotary switch, providing a variable means of converting the circuit's output impedance. Audio speakers are available with a plurality of impedance values, therefore, the taps on the secondary side of the output transformer are designed to match the plurality of impedance values of common audio speakers. The circuit's multiple position rotary switch provides a variable means of selecting the appropriate output transformer tap that matches the audio speaker's impedance.

### BRIEF DESCRIPTION OF THE DRAWINGS

FIG. 1 is a general block diagram.

FIG. 2 is schematic diagram.

### DRAWINGS

### Reference Numerals

1 guitar tube amplifier

S1 multi-position rotary switch

2 multiple tapped input transformer

S2A, S2B dual pole, multiple position rotary switch

3 multiple tapped, series resistive ladder network

4 multiple tapped output transformer

S3 multiple position rotary switch

5 audio speaker

### DETAILED DESCRIPTION OF THE DRAWINGS

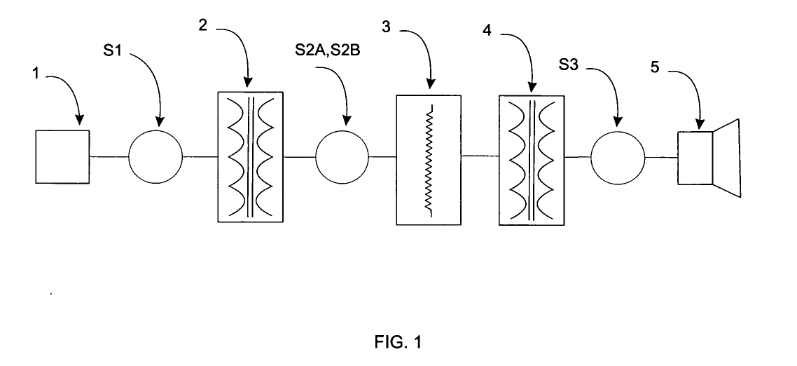

FIG. 1, the guitar tube amplifier 1 whose output is coupled to the input of this invention, a multiple position rotary switch S1. The multiple position rotary switch S1 is coupled to each of the taps on the primary side of a multiple tapped input transformer 2. The taps on the secondary side of the input transformer 2 are coupled to input side of a dual pole, multiple position rotary switch S2A. The output side of the dual pole, multiple position rotary switch S2B is coupled to the multiple taps on the input side of a series resistive ladder network 3. The output side of the series resistive ladder network 3 is coupled in a series only method to the primary side of a output transformer 4. Each of the multiple taps on the secondary side of the output transformer 4 is coupled to a multiple position rotary switch S3. The multi-position rotary switch S3, which completes this invention, is coupled to an audio speaker 5.

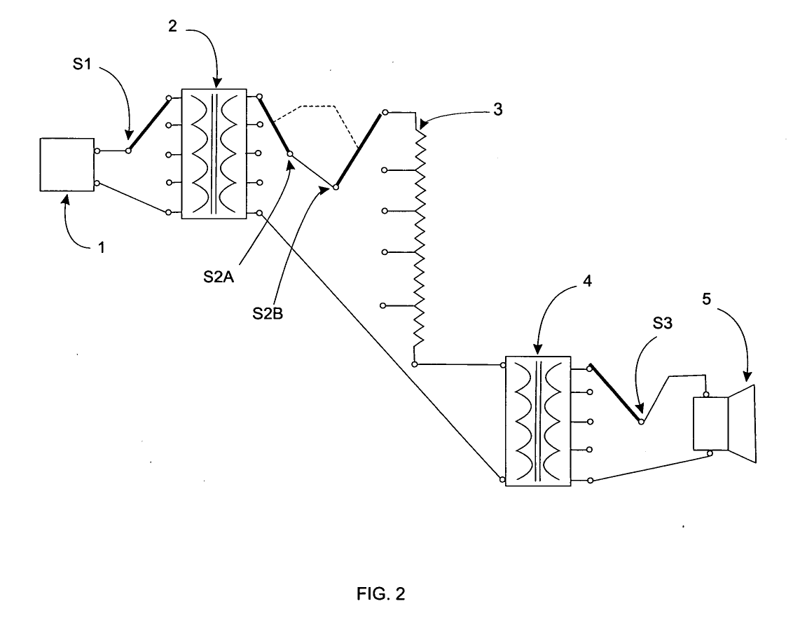

FIG. 2, the output section of a guitar tube amplifier 1 is coupled to a multiple position rotary switch of this invention S1. The multiple position rotary switch S1 is coupled to each of the taps on the primary side of a multiple tapped input transformer 2. The multiple taps of the input transformer 2 are wound to match a plurality of impedance values available in common guitar tube amplifiers 1. The multiple tapped input transformer 2 and the multiple position rotary switch S1 provide a variable means of converting the impedance of the circuit to match the impedance of the output section of common guitar tube amplifiers 1.

The taps on the secondary side of the input transformer 2 are coupled to the input side of a dual pole, multiple position rotary switch S2A. The taps on the secondary side of the input transformer 2 are wound specifically to match the impedance of each of the corresponding taps of a multiple tapped, series resistive ladder network 3, including the combined impedance of a multiple tapped output transformer 4 and an audio speaker 5.

The output side of the dual pole, multi-position rotary switch S2B is coupled to the series resistive ladder network 3, providing a variable means of controlling the power to the audio speaker 5. The resistive ladder network 3 is coupled to the audio speaker 5 in a series only method.

The output side of the series resistive ladder network 3 is coupled to the primary side of the output transformer 4. The taps on the secondary side of the multiple tapped output transformer 4 are coupled to the multiple position rotary switch S3. The taps on the secondary side of the multiple tapped output transformer 4 are wound to match a plurality of impedance values available in common audio speakers 5.

The multiple tapped output transformer 4 and the multiple position rotary switch S3 provide a variable means of converting the impedance of the audio speaker 5, matching the impedance requirement of the circuit. The plurality of all the electrical components in the circuit provide a variable means of matching the combined impedance of circuit and audio speaker 5, to the plurality of output impedance values available in common guitar tube amplifiers 1.

Thus, it can be seen that the disclosed circuit in accordance with the present invention provide a new and improved speaker volume control for guitar tube amplifiers, in a method that does not reduce the audio speaker's reactance, allowing the audio speaker to reproduce a natural sound,.

The new and improved circuit provides a means for maintaining a matched and constant load impedance on the output stage of the guitar tube amplifier, throughout the volume control range.

The new and improved circuit provides a means for separate input and output impedance conversion, allowing a guitar tube amplifier and an audio speaker with dissimilar impedance values to be impedance matched to the circuit.

Although the particular preferred embodiment of the invention have been described and illustrated herein, it is recognized that modifications and variations may readily occur to those skilled in the art. It is therefore intended that the claims be interpreted to cover such modifications and variations.

I claim:

1. A passive, variable volume control circuit that couples between a music instrument tube amplifier and an audio speaker without utilizing a resistive load in parallel with the audio speaker.

2. A passive, variable volume control circuit as claimed in claim 1, wherein said variable input impedance means comprises of a multiple position rotary switch and a multiple tapped input transformer.

3. A passive, variable volume control circuit as claimed in claim 1, wherein said variable volume control means one of plurality volume levels, comprises of a dual pole, multiple position rotary switch, coupled to a multiple tapped input transformer and a series resistive ladder network.

4. A passive, variable volume control circuit as claimed in claim 1, wherein said variable output impedance means comprises of a multiple position rotary switch and a multiple tapped output transformer.

5. A passive, variable volume control circuit as claimed in claim 1, wherein the plurality of electrical components maintain a matched and constant load impedance to the output section of the music instrument tube amplifier.

6. A passive, variable volume control circuit as claimed in claim 1, wherein the plurality of electrical components provide a means of converting the impedances of both the music instrument tube amplifier and separately, the audio speaker, each with dissimilar impedance values, to match the impedance requirement of the volume control circuit.
